(19) United States
(12) Patent Application Publication
(10) Pub. No.: US 2012/0081866 A1
(43) Pub. Date: Apr. 5, 2012

(54) BRACKETS FOR ELECTRICAL COMPONENTS

(75) Inventors: Paul Wickett, Northville, MI (US); Bernd Eckert, Baden-Wuerttemberg (DE); Rajesh Das, Canton, MI (US)

(73) Assignee: ROBERT BOSCH GMBH, Stuttgart (DE)

(21) Appl. No.: 12/896,575

(22) Filed: Oct. 1, 2010

(51) Int. Cl. H05K 7/00; H05K 1/16

(52) U.S. Cl. 361/760; 174/260

(57) ABSTRACT

An apparatus includes, in combination, an electrical component and a bracket. The electrical component has a first end configured to electrically connect to a circuit board. The electrical component defines an axis and has a width measured in a direction transverse to the axis. The bracket has a body defining a bore shaped to receive the electrical component. The body further includes a break in communication with the bore to allow expansion of the bore. In an at-rest state of the bracket, the bore has a bore width smaller than the width of the electrical component, and when the electrical component is received in the bore, the bracket is elastically deformed such that the electrical component is clamped in the transverse direction solely by the residual stress within the bracket without any additional clamp or fastener.

### BACKGROUND

The present invention relates to brackets for mounting large electrical components to circuit boards.

Conventionally, large electrical components (i.e., components such as electrolytic capacitors and inductors that are much larger than common microprocessors) are coupled to a printed circuit board with additional means besides the pins that provide the electrical connection. Often, heat shrinkable tubing and/or thermally conductive glue are used for this purpose.

### SUMMARY

In one embodiment, the invention provides an apparatus comprising, in combination, an electrical component and a bracket. The electrical component has a first end configured to electrically connect to a circuit board. The electrical component defines an axis and has a width measured in a direction transverse to the axis. The bracket has a body defining a bore shaped to receive the electrical component. The body further includes a break in communication with the bore to allow expansion of the bore. In an at-rest state of the bracket, the bore has a bore width smaller than the width of the electrical component, and when the electrical component is received in the bore, the bracket is elastically deformed such that the electrical component is clamped in the transverse direction solely by the residual stress within the bracket without any additional clamp or fastener.

In another embodiment the invention provides a circuit board assembly comprising a circuit board, a first electrical component electrically connected to the circuit board, a first bracket holding the first electrical component and being coupled to the circuit board, a second electrical component electrically connected to the circuit board, and a second bracket holding the second electrical component and being coupled to the circuit board. The second electrical component has a height in a direction perpendicular to the circuit board that is different than a corresponding height of the first electrical component. The first and second brackets are of substantially identical height in a direction perpendicular to the circuit board when coupled thereto, and the height of the first and second brackets is at least as large as the taller of the two electrical components.

Other aspects of the invention will become apparent by consideration of the detailed description and accompanying drawings.

### BRIEF DESCRIPTION OF THE DRAWINGS

FIG. 1 is a perspective view of a first bracket embodying the invention.

FIG. 2 is a perspective view of the bracket of FIG. 1 holding three electrical components.

FIG. 3 is a perspective view of an alternate bracket embodying the invention.

FIG. 4 is a perspective view of the bracket of FIG. 3 holding an electrical component.

FIG. 5 is a perspective view of a circuit board assembly having a plurality of electrical components mounted to a circuit board with various brackets.

FIG. 6 is a perspective view illustrating a bottom side of the circuit board assembly and including a housing coupled to the circuit board and at least partially enclosing the plurality of electrical components shown in FIG. 5.

FIG. 7 is a perspective view of the housing of FIG. 6, separate from the circuit board.

FIG. 8 is a partially cutaway perspective view of the circuit board assembly of FIG. 5 illustrating fasteners coupling at least one of the various brackets of FIG. 5 to the circuit board.

Before any embodiments of the invention are explained in detail, it is to be understood that the invention is not limited in its application to the details of construction and the arrangement of components set forth in the following description or illustrated in the following drawings. The invention is capable of other embodiments and of being practiced or of being carried out in various ways.

### DETAILED DESCRIPTION

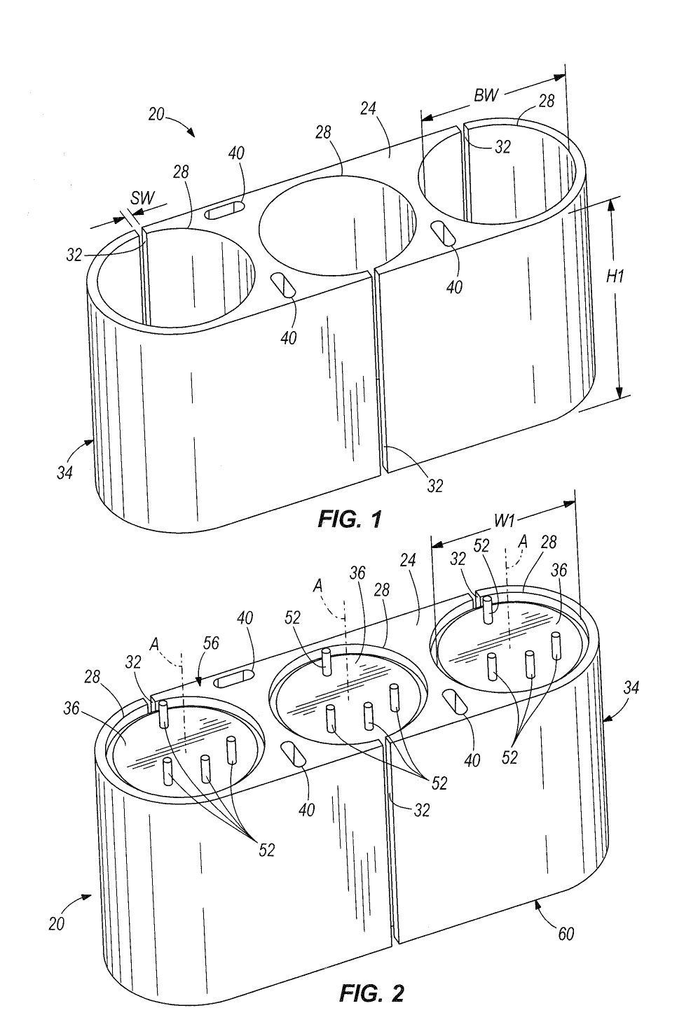

FIGS. 1 and 2 illustrate a bracket 20 including a body 24 having three bores 28, although one, two, or more than three bores may alternately be provided. Each of the bores 28 defines a bore width BW in a direction transverse to an axis of extension A (FIG. 2). As illustrated, the bore widths BW are diameters of the bores 28, which are circular in cross-section. Although not required, the bore widths BW of all three bores 28 are the same in the illustrated construction. Each of the bores 28 extends fully through the body 24, defining an axial length equal to the height H1 of the bracket 20. Breaks are formed in the body 24 in the form of slits 32 in communication with each of the respective bores 28. The slits 32 extend along the entire axial length of the bores 28. Although the ratio may vary in other constructions, each slit 32 has a width SW that is less than one-fourth the bore width BW when the bracket 20 is in an at-rest (i.e., unstressed) state as shown in FIG. 1. An outer perimeter surface 34 is defined by the body 24. The entire outer perimeter surface 34 is devoid of projections, and the only breaks in the surface 34 are the slits 32.

As shown in FIG. 2, the bores 28 of the bracket 20 are sized and shaped to correspond to specific components, such as the illustrated electrolytic capacitors 36 that have widths W1 measured transverse to their axes, which are shared with the respective bore axes A. In the illustrated construction, the widths W1 are diameters for the cylindrical capacitors 36. More particularly, the bore width BW of each bore 28 is slightly smaller than the width W1 of the corresponding capacitor 36 when the bracket 20 is in the at-rest state. This allows the capacitors 36 to be clamped within the bracket 20 with a self-contained clamping force as described in further detail below. The capacitors 36 are fully inserted into the respective bores 28 due to the height H1 of the bracket 20 being equal to or greater than the body length of the capacitors 36 (not including electrical connector pins 52). In other words, no portion of any one of the capacitors 36, except the connector pins 52, extends axially beyond the bounds of the bracket 20. The bracket 20 is configured to accommodate components other than the illustrated capacitors 36 as long as they have a similar width that is slightly larger than the bore width BW, regardless of the axial length of the component(s) (although, in some instances it is desired to keep the axial length of each of the inserted components no larger than the bracket height H1).

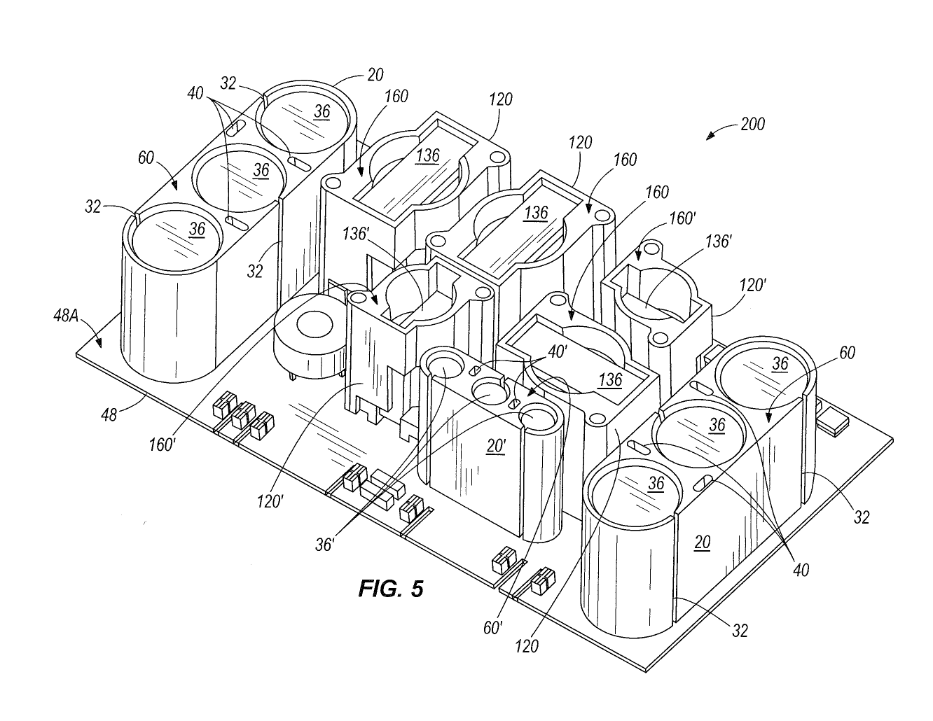

The bracket 20 includes a plurality of mounting apertures 40 configured to receive corresponding fasteners 44 (FIG. 8) that can be used to attach the bracket 20 to a circuit board 48 (FIGS. 5, 6, and 8). Although three apertures 40 are illustrated, more or less than three can alternately be provided. Each of the apertures 40 has an elongated hole cross-sectional shape (i.e., slotted or oval) to allow for some amount of adjustability and tolerance when coupled to the circuit board 48. Two of the apertures 40 are located adjacent a common side of the bracket 20 and are elongated in parallel directions. The third aperture 40 is positioned across from one of the two parallel apertures 40. The third aperture 40 is elongated in a direction substantially perpendicular to the other two apertures 40. All of the apertures 40 extend fully through the body 24. Although the bracket 20 is symmetrical to accept the capacitors 36 from either end, the end of the bracket 20 adjacent the electrical connector pins 52 is arbitrarily referred to as the base surface 56, and the opposite end is referred to as the top surface 60 (FIG. 2).

To insert one of the capacitors 36 into the bracket 20 for mounting to the circuit board 48, a spreader tool is inserted into the slit 32 corresponding to the desired bore 28, and the spreader tool is operated to spread apart the adjacent walls of the slit 32. This causes an elastic deformation of the body 24 that increases the size of the bore 28 (i.e., increasing the effective bore width BW to a dimension larger than the at-rest bore width BW and at least as large as the width W1 of the capacitor 36). When the slit 32 is spread, the capacitor 36 can be inserted into the bore 28 with little or no frictional resistance. Once the capacitor 36 is inserted to the desired depth and oriented as desired, the spreader tool is released, and the body 24 tries to return to its natural state. However, due to the width W1 of the capacitor 36 being slightly larger than the at-rest bore width BW, a slight residual stress is maintained in the material of the body 24. This residual stress exerts a clamping force on the capacitor 36 in a direction transverse to the axis A to hold the capacitor 36 firmly in place. Thus, the capacitor 36 is gripped or clamped firmly in place by a self-contained force without any additional components (e.g., movable or adjustable clamp members and/or fasteners).

The difference between capacitor width W1 and bore width BW is large enough to securely clamp the capacitors 36, but small enough that the bracket 20 does not yield while being stretched during assembly and does not exceed a predetermined contact stress on the capacitors 36 after assembly. In some constructions, a thermal fit is used to clamp the capacitors 36 in the bracket 20, and the slits 32 may or may not be necessary. In a thermal fitting process, the assembly is done with the bracket 20 and/or the capacitors 36 at a reduced temperature. When the components reach ambient or elevated temperatures, the capacitors 36 are securely clamped in the bracket 20.

If the bracket 20 includes multiple bores 28, as is the case with the illustrated bracket 20, the above described process can be repeated until capacitors 36 are inserted and clamped in each of the bores 28. Once all of the desired capacitors 36 are within the bracket 20, the bracket 20 is coupled to a first side 48A of the circuit board 48. The pins 52 of the capacitors 36 are received in corresponding apertures of the circuit board to establish the desired electrical connections. The base surface 56 of the bracket 20 makes surface contact with the first side 48A of the circuit board in the area directly surrounding the area of the electrical connections. The fasteners 44, which are screws in the illustrated construction, extend from a second side 48B of the circuit board 48 (i.e., the back side which is opposite the first side 48A) through apertures 64 in the circuit board 48 to engage the apertures 40 in the bracket 20. The bracket 20, along with the capacitors 36 therein, are mounted firmly to the circuit board 48 to avoid damage by vibration without heat shrinkable tubing or gluing. Although screws are illustrated, the bracket 20 may be coupled with the circuit board 48 with snap hooks, rivets, and/or dovetails, among other things.

The three bores 28 of the illustrated bracket 20 are disposed in a single row, although other configurations are optional. The slits 32 are staggered on opposite sides of the body 24 such that adjacent pairs of bores 28 do not have their slits 32 on the same side of the body 24, but rather on opposite sides of the body 24. In some constructions, the body 24 allows only a limited amount of elastic deformation.

The bracket 20 forms a strong thermal coupling with the capacitors 36 therein due to a large amount of surface contact. The thermal coupling allows effective cooling of the capacitors 36 as heat is drawn into the bracket 20. The bracket 20 can be constructed of aluminum or other metals. Alternately, the bracket 20 can be constructed of one or more different types of plastics, including standard and/or heat conductive types.

The illustrated bracket 20 can be manufactured as a one-piece extrusion. The extrusion can be produced to any desired length, and lengths shorter than the extrusion length can be produced by cutting (e.g., sawing) the extrusion to a desired length. Alternately, the bracket 20 can be machined, die-cast, or molded.

Although the bracket 20 can include bores having shapes other than cylindrical, the cylindrical bores 28 in the illustrated construction are well-suited for a variety of electrical components or other items, which may or may not have well-established standardized sizing. For example, the bracket 20 can be particularly useful for all types of battery cells (which are typically cylindrical, have standardized sizing, and benefit from good thermal transfer for cooling). The bracket 20 is especially useful for big battery cells, such as traction batteries for electric vehicles and other high power batteries.

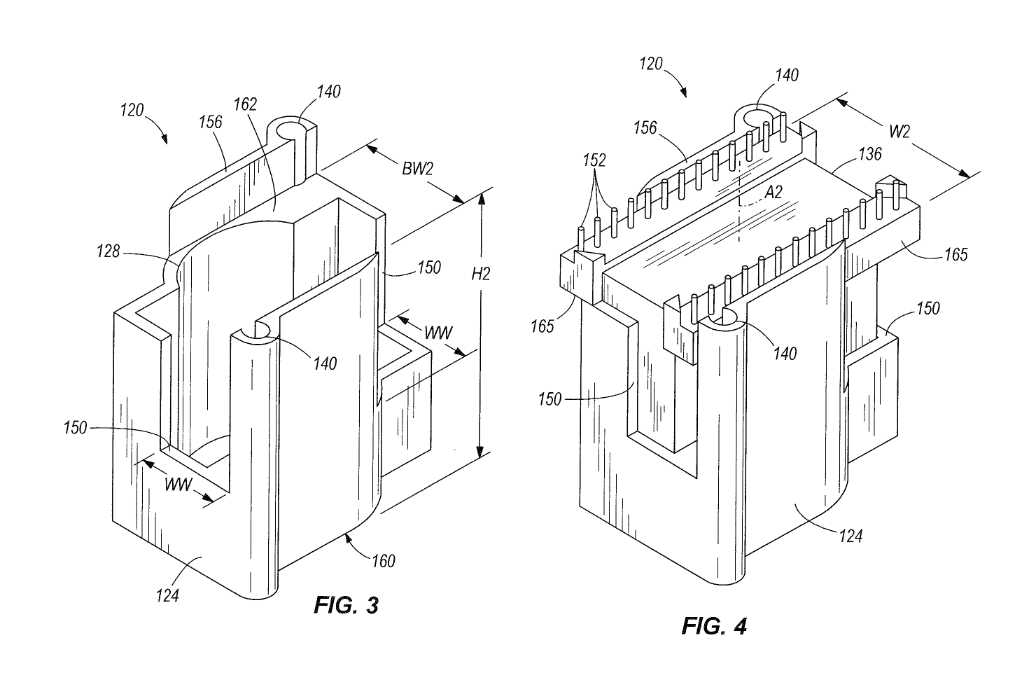

Turning now to FIGS. 3 and 4, a bracket 120 is illustrated for holding a non-cylindrical electrical component, such as an inductor 136 having one or more substantially flat sides. The bracket 120 holds the inductor 136 as shown in FIG. 4. Particularly, the bracket 120 includes a body 124 defining a bore 128 having a bore width BW2 in a direction transverse to an axis of extension A2 (FIG. 4). The bore 128 can extend fully through the body 124. The bore width BW2 is configured to correspond very closely to the size and shape of the inductor 136, but the bore width BW2 is configured to be slightly smaller than a width W2 of the inductor 136 when the bracket 120 is in an at-rest state.

The body 124 has a discontinuous perimeter having breaks therein in the form of a pair of opposed recesses or windows 150 that allow the bore width BW2 to be slightly increased by elastic deformation to match the width W2 of the inductor 136. Thus, residual stress in the body 124 exerts a clamping force on the inductor 136 in a direction transverse to the axis A2 to hold the inductor 136 firmly in place so that it is gripped or clamped firmly in place without any additional components (e.g., movable or adjustable clamp members and/or fasteners). One of the windows 150, shown on the right hand side of FIG. 3, spans across portions of two different sides of the body 124 (i.e., extending around an imaginary corner). The other window 150, shown on the left hand side of FIG. 3, is positioned in one substantially flat side of the body 124. The particular configuration of the body 124 (e.g., the material properties, the wall thickness, the number, size, and shape of breaks, etc.) determines the amount of elastic deformation, the amount of residual stress, and ultimately, the clamping performance of the bracket 120. In the illustrated construction, both windows 150 have an at-rest width WW that is greater than one-fourth the bore width BW2, and in some constructions is between about one-third and three-fourths the bore width BW2.

The body 124 further includes a pair of apertures 140 that extend fully through the body 124. In the illustrated construction, the two apertures 140 are positioned diagonally across from each other at opposite ends of the body 124. The bracket 120 is configured to be coupled to the circuit board 48 in much the same way as the bracket 20 of FIGS. 1 and 2. Once the inductor 136 is within the bracket 120, the bracket 120 is coupled to the first side 48A of the circuit board 48. Pins 152 of the inductor 136 are received in corresponding apertures of the circuit board 48 to establish the desired electrical connections. A base surface 156 of the bracket 120 makes surface contact with the first side 48A of the circuit board 48 in the area directly surrounding the area of the electrical connections. Fasteners 144 (FIG. 8), which are screws in the illustrated construction, extend from a second side 48B of the circuit board 48 (i.e., the back side which is opposite the first side 48A) through apertures 64 in the circuit board 48 to engage the apertures 140 in the bracket 120. The bracket 120, along with the inductor 136 therein, is mounted firmly to the circuit board 48 to avoid damage by vibration without heat shrinkable tubing or gluing. Although screws are illustrated, the bracket 120 may be coupled with the circuit board 48 with snap hooks, rivets, and/or dovetails, among other things.

The overall height H2 of the bracket 120 is measured from the base surface 156 to a top surface 160. A secondary base surface 162 (FIG. 3) is recessed a short distance from the base surface 156. The secondary base surface 162 is substantially parallel to the base surface 156 and provides a contact surface for an extending ridge 165 of the inductor 136 to abut when inserted into the bracket 120 (FIG. 4).

Further features of the bracket 120, such as materials, methods of manufacturing, and thermal transfer, among others, are similar to the bracket 20 of FIGS. 1 and 2, and reference is hereby made to the above description of such features.

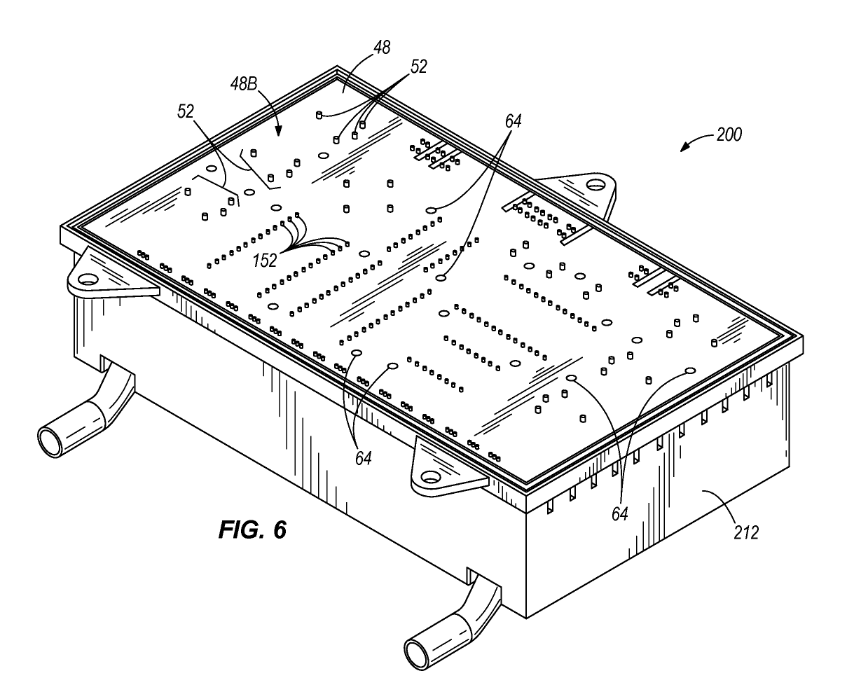

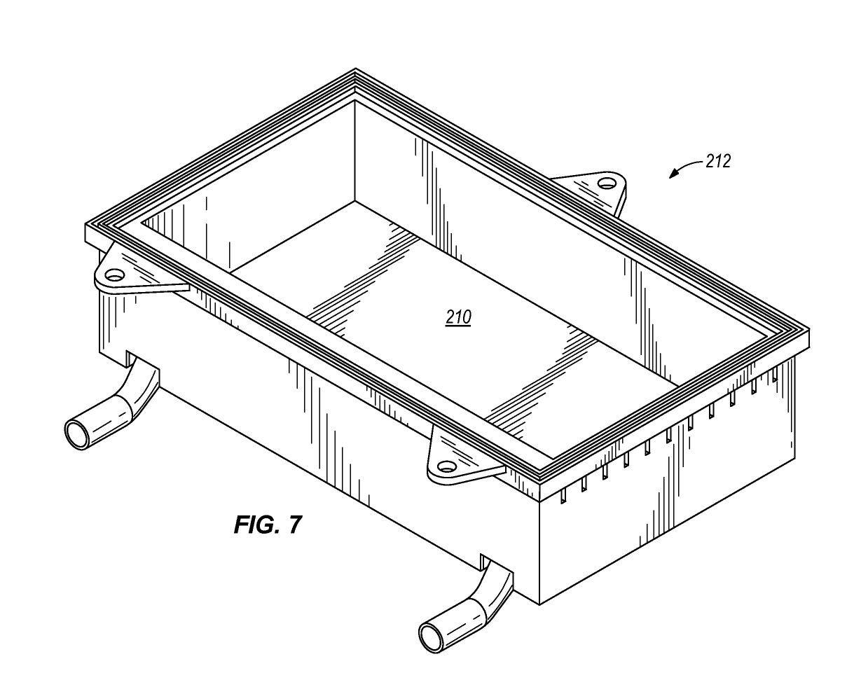

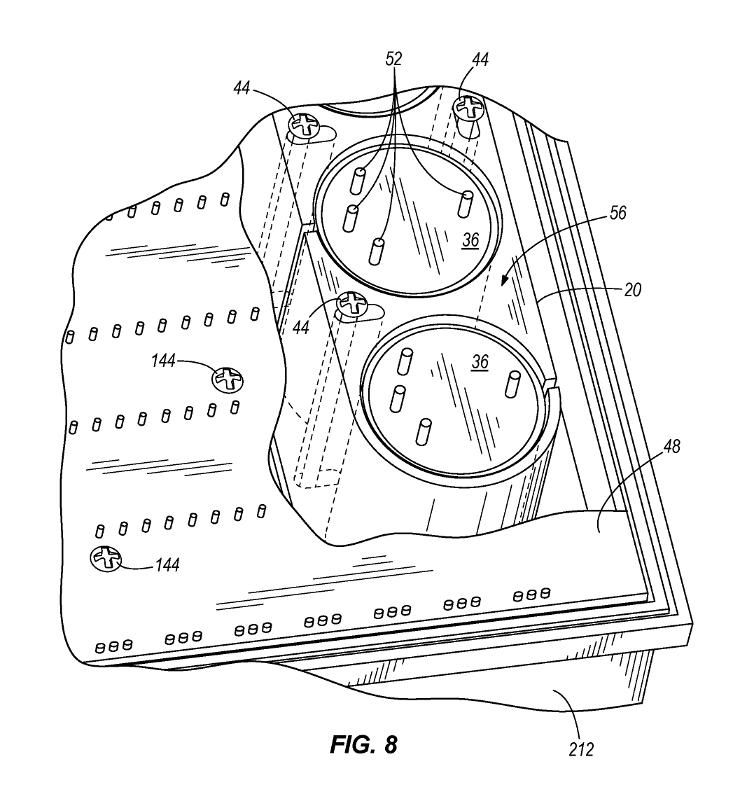

FIGS. 5 and 6 illustrate a circuit board assembly 200 including the circuit board 48 and a plurality of the capacitors 36 and the inductors 136 that are coupled to the circuit board 48 with the respective brackets 20, 120. Furthermore, an alternate bracket 20′ is illustrated with a plurality of alternate capacitors 36′ therein. The alternate bracket 20′ is nearly identical to the bracket 20 of FIGS. 1 and 2 except for being scaled down in size. The alternate bracket 20′, however, only includes two mounting apertures 40′ compared to the three mounting apertures 40 of the bracket 20. Alternate brackets 120′ are also illustrated in FIG. 5, holding alternate inductors 136′ therein. Each of the alternate brackets 120′ is nearly identical to the bracket 120 of FIGS. 3 and 4 except for being scaled down in size. The illustrated combination of components and brackets 20, 20′, 120, 120′ in FIG. 5 is shown merely by way of example.

As can be seen in FIG. 5, the various electrical components 36, 36′, 136, 136′ have different axial lengths or heights measured perpendicular to the plane of the circuit board 48. However, each and every one of the brackets 20, 20′, 120, 120′ is of the same height so that the top surfaces 60, 60′, 160, 160′ of all of the brackets define a common plane when all of the brackets are mounted to the circuit board 48. The plane defined by the top surfaces 60, 60′, 160, 160′ is shared by an interior surface 210 of a housing 212 that is coupled to the circuit board 48, at least partially enclosing the electrical components 36, 36′, 136, 136′ and the brackets 20, 20′, 120, 120′. Plane contact between the brackets 20, 20′, 120, 120′ and the interior surface 210 of the housing 212 increases the stability of the mounting of all of the components 36, 36′, 136, 136′ to the circuit board 48 and also enhances the rigidity of the overall circuit board assembly 200 by reinforcing the housing 212.

Thus, the invention provides, among other things, a bracket configured to exert a self-contained clamping force on one or more large electrical components. Multiple brackets mounted to a circuit board define a common plane, parallel to and spaced a distance from the circuit board, that is shared with a housing member. All of the brackets are at least as tall as the tallest electrical component in a given circuit board assembly. Various features and advantages of the invention are set forth in the following claims.

What is claimed is:

1. An apparatus comprising in combination:
an electrical component having a first end configured to electrically connect to a circuit board, the electrical component defining an axis and having a width measured in a direction transverse to the axis; and
a bracket having a body defining a bore shaped to receive the electrical component, the body further including a break in communication with the bore to allow expansion of the bore, wherein the bore extends fully through the body and the break extends along an entire axial length of the bore,
wherein in an at-rest state of the bracket, the bore has a bore width smaller than the width of the electrical component, and when the electrical component is received in the bore, the bracket is elastically deformed such that the electrical component is clamped in the transverse direction solely by the residual stress within the bracket without any additional clamp or fastener.

2. The apparatus of claim 1, wherein the body defines an additional bore and an additional break that are substantially identical to the first bore and the first break, and the combination further comprises an additional electrical component that corresponds to the additional bore and is substantially identical to the first electrical component.

3. The apparatus of claim 2, wherein the two breaks are on substantially opposite sides of the body.

4. The apparatus of claim 1, wherein the body is a one-piece extrusion.

5. (canceled)

6. The apparatus of claim 1, wherein the body further includes a plurality of fastener-receiving apertures, each of which extends fully through the body.

7. The apparatus of claim 1, wherein the break is a slit having a width that is less than one-fourth the bore width.

8. (canceled)

9. A circuit board assembly comprising:
a circuit board;
a first electrical component electrically connected to the circuit board;
a second electrical component electrically connected to the circuit board, the second electrical component having a height in a direction perpendicular to the circuit board that is different from a corresponding height of the first electrical component;
a first bracket holding the first electrical component and being coupled to the circuit board; and
a second bracket holding the second electrical component and being coupled to the circuit board,
wherein the first and second brackets are of substantially identical height in a direction perpendicular to the circuit board when coupled thereto, and the height of the first and second brackets is at least as large as the taller of the two electrical components, wherein the first bracket has a body defining a bore shaped to receive the first electrical component, the body of the first bracket further including a break in communication with the bore to allow expansion of the bore, and wherein the bore of the first bracket extends fully through the body and the break extends along an entire axial length of the bore.

10. The circuit board assembly of claim 9, further comprising a housing coupled to the circuit board and at least partially enclosing the first and second electrical components.

11. The circuit board assembly of claim 10, wherein respective ends of the first and second brackets that are remote from the circuit board define a common plane when coupled to the circuit board, the common plane being shared with an interior surface of the housing when the housing is coupled to the circuit board.

12. The circuit board assembly of claim 9, wherein the first and second electrical components are coupled to a first side of the circuit board, and the first and second brackets are coupled to the circuit board with a plurality of fasteners that extend from a side of the circuit board opposite the first side.

13. The circuit board assembly of claim 12, wherein the first and second electrical components are coupled to the first side of the circuit board without any adhesive.

14. (canceled)

15. The circuit board assembly of claim 9, wherein in an at-rest state of the first bracket, the bore has a bore width smaller than a width of the first electrical component, and when the first electrical component is received in the bore, the first bracket is elastically deformed such that the first electrical component is clamped solely by the residual stress within the bracket without any additional clamp or fastener.

16. The circuit board assembly of claim 15, wherein the break is a slit having a width that is less than one-fourth the bore width.

17. (canceled)

18. The circuit board assembly of claim 9, wherein the first bracket defines an additional bore that is shaped to receive a third electrical component, the first bracket further including a break in communication with the additional bore to allow expansion of the additional bore, wherein the two breaks in the first bracket are on substantially opposite sides of the first bracket.

19. The circuit board assembly of claim 9, wherein the first bracket is a one-piece extrusion.

20. (canceled)

21. The circuit board assembly of claim 9, wherein the second bracket has a body defining a bore shaped to receive the second electrical component, the body of the second bracket further including a break in communication with the bore to allow expansion of the bore, and wherein the bore of the second bracket extends fully through the body and the break of the second bracket extends along an entire axial length of the bore.

22. The circuit board assembly of claim 21, wherein the second bracket is a one-piece extrusion.
